(19) United States
(12) Patent Application Publication
(10) Pub. No.: US 2024/0337607 A1
(43) Pub. Date: Oct. 10, 2024

(54) METHOD AND APPARATUS FOR DETERMINING QUALITY OF SEMICONDUCTOR CHIP

(71) Applicant: OPTO SYSTEM CO., LTD., Kyotanabe City, Kyoto (JP)

(72) Inventor: Kenichi IKEDA, Kyotanabe City, Kyoto (JP)

(73) Assignee: OPTO SYSTEM CO., LTD., Kyotanabe City, Kyoto (JP)

(21) Appl. No.: 18/293,570

(22) PCT Filed: Aug. 5, 2021
(86) PCT No.: PCT/JP2021/029109

§ 371 Date: Jan. 30, 2024

(51) Int. Cl. G01N 21/95; G01N 21/88; G01N 21/94; G06T 7/00; G06T 7/13

(52) U.S. Cl. CPC G01N 21/9503; G01N 21/8851; G06T 7/001; G06T 7/13; G01N 2021/8887; G01N 21/94; G06T 2207/30148; G06T 2207/30168

(57) ABSTRACT

An apparatus and method for quickly and reliably determining the state of quality of an end surface of a semiconductor chip, including a first process for extracting data on an evaluation line extending continuously inside and outside a semiconductor chip; a second process for assessing a mode of change in the data on the evaluation line so as to specify an optimum image; and a third step for determining the quality of the semiconductor chip corresponding to the optimum image on the basis of a reference image acquired in advance.

### TECHNICAL FIELD

The present invention relates to a method and apparatus for quickly and reliably determining the quality of a chip's end surface (side surface) in the process of manufacturing semiconductor chips such as semiconductor laser diodes (LDs).

### BACKGROUND

LD chips generally have a double heterostructure, in which an active layer emitting light at a laser emission wavelength is sandwiched between a P-type cladding layer and an N-type cladding layer.

When a forward voltage is applied between the P-type layer and the N-type layer, both end surfaces of the active layer function as reflecting mirrors, causing the laser light to be amplified and reciprocated within the active layer for stimulated emission. Here, edge-emitting lasers can be roughly divided by reflective structure into, Fabry-Perot lasers utilizing a semiconductor cleavage plane as a reflector, Distributed Feedback lasers (DFBs) forming a diffraction grating in a waveguide, and Distributed Bragg Reflector lasers (DBRs) forming diffraction gratings before and after the active region, etc.

In such these semiconductor chips, it is necessary, for example, at the final stage of manufacturing, to judge whether the stimulated emission port formed on the chip's end surface is free from scratches and dust.

### PRIOR ART LITERATURE

### Patent Literature

Patent Document 1: JP 2017-207356A
Patent Document 2: JP 2002-296203 A
Patent Document 3: JP 10-040387A
Patent Document 4: JP-H10-002725A

Although various types of inventions including patent documents 1-4 are known with respect to quality determination apparatuses, there is no known technique for efficiently determining the quality state of the end surfaces for a large number of semiconductor chips arranged vertically and horizontally. That is, the above mentioned inventions mainly target the upper surfaces of the chips, and are not configured to be able to reliably determine the quality of the side surfaces (end surfaces) of modern semiconductor chips, which are becoming smaller and smaller.

### SUMMARY OF THE INVENTION

It is an object of the present invention to provide a method and apparatus for determining the quality of the end surface of a semiconductor chip quickly and reliably.

### Means for Solving the Problem

In order to achieve the above object, an apparatus for determining a semiconductor chip according to the present invention, has an imaging device that reciprocates obliquely above the semiconductor chip disposed on a light-reflective mounting surface to capture an image of the semiconductor chip's end surface, and a determination device that determines the quality of the semiconductor chip based on the image captured by the imaging device.

Wherein the determination device comprises: a first means for extracting data on an evaluation line continuous inside and outside of the semiconductor chip from each of a plurality of images captured during the movement of the imaging device; a second means for identifying an optimum image from the plurality of images by evaluating the change mode of data on the evaluation lines for each of said images; and a third means for determining the quality of the semiconductor chip by assessing the optimal image identified by the second means based on a previously captured standard image.

Also, a method for determining a semiconductor chip according to the present invention is realized by using an imaging device and a determination device; the imaging device that reciprocates obliquely above the semiconductor chip disposed on a light-reflective mounting surface to capture an image of the semiconductor chip's end surface, the determination device that determines the quality of the semiconductor chip based on the image captured by the imaging device.

Wherein the method comprises: a first step of extracting data on an evaluation line continuous inside and outside of the semiconductor chip from each of a plurality of images captured during the movement of the imaging device; a second step of identifying an optimum image from the plurality of images by evaluating the change mode of data on the evaluation lines for each of said images; and a third step of determining the quality of the semiconductor chip by assessing the optimal image identified by the second step based on a previously captured standard image.

According to the present invention, since there is no need to hold the end surface (side surface) 10a of the thin semiconductor chip 10 on a horizontal plane, efficient high-precision quality inspection can be realized. The semiconductor chip 10 is preferably arranged vertically and horizontally in terms of inspection efficiency, but is not necessarily limited to the alignment arrangement shown in FIG. 1 (b).

In addition, the present invention can widely capture the end surface (side surface) of the thin plate-like chip, because the imaging device EQU, capturing an enlarged image of the semiconductor chip 10, reciprocates obliquely above the semiconductor chip 10 positioned on the mounting surface with light reflectivity. To capture a broad range of end face, it is advantageous to have a small inclination angle θ with respect to the mounting surface during the reciprocating movement of the imaging device. However, if the angle is too small, optical components such as the objective lens may come into contact with the mounting surface or the semiconductor chip 10.

Taking this into account, the staggered arrangement shown in FIG. 1(c) is more effective than the aligned arrangement shown in FIG. 1(b). This is because the staggered arrangement ensures wider gaps (W2) between semiconductor chips 10 in the direction of the illumination light 20 compared to gaps (W1) of the aligned arrangement.

For a multitude of semiconductor chips 10 arranged both vertically and horizontally, a transmitted light microscope is unsuitable for evaluating the quality of each chip's end surface 10a. Therefore, in the present invention, a reflected light microscope shown in FIG. 2(a) is employed, and the imaging device of the present invention is structured with the reflected light microscope and an external illumination 4.

As shown in FIG. 2 (a), the reflected light microscope is generally configured with an objective lens 1 facing a sample 6, an imaging lens 2 for imaging captured light 30 onto an image sensor 7, an illumination lens 3 for receiving illumination light 20, a splitter 5 for guiding the illumination light 20 passed through the illumination lens 3 to the sample 6, and a light source 4 for generating the illumination light 20. As shown, the captured light 30, which is a reflected wave from the chip's end surface 10a (sample 6), passes through the splitter 5 and is guided to the image sensor 7.

In this context, if the tilt angle θ is too small, the adjacent chip 10 in the camera direction may obstruct the illumination light, introducing unwanted speckle noise to the directly reflected wave from the edge surface 10a of the chip in question. On the other hand, if the tilt angle θ is too large, the end surface 10a cannot be captured widely. Therefore, taking into account the array pitch (W1/W2) of the semiconductor chips 10 in the illumination direction, and the height dimension of the inspection range on the chip's end surface 10a, the tilt angle θ is preferably determined within the range of 20° to 40°.

Additionally, the determination apparatus according to the present invention extracts data on an evaluation line continuous inside and outside of the semiconductor chip 10 from each of a plurality of images captured during the movement of the imaging device EQU (first means). The extraction of data on the evaluation line may involve real-time processing synchronized with the capturing processing of the imaging device or batch processing for the plurality of images.

In the present invention, multiple images are captured during the movement of the imaging device EQU to acquire an image of the semiconductor chip 10 in precise focus. That is, in the present invention, a plurality of images are acquired during the process of moving the imaging device EQU forward or backward from a tentatively positioned state to a limit position, and from among these images, the optimal image in focus is selected.

FIG. 2 (c) is a block diagram illustrating a configuration of the imaging device EQU capable of reciprocating in the X direction and the Z direction. As shown, the Z-direction of the present invention forms a tilt angle θ with respect to the X-direction. The mounting table 40, which holds semiconductor chips 10, is configured to be arbitrarily movable in the vertical direction, biaxial orthogonal direction on the horizontal plane, and in a tilt direction, based on a camera through which the semiconductor chips 10 are viewed in a plan view.

As shown in FIG. 2(c), the imaging device EQU includes a stepping motor Mx that enables reciprocating movement in the X direction; a horizontal slide stand 45 capable of reciprocating in the X direction based on a first ball screw mechanism and the rotation of the stepping motor Mx; a slide unit 44 that incorporates a second ball screw mechanism and the stepping motor Mz; and a slide stand 43 and imaging body 42 that can reciprocate in the inclined direction along the slide unit 44.

Illumination light 20 is directed into the imaging body 42, illuminating the end surface 10a of the semiconductor chip 10 through the objective lens 1. The reflected wave from the chip's end surface 10a is then captured as imaging light by the image sensor 7 of the imaging camera 41.

Incidentally, the multiple captured images must include an accurately focused image in the inspection area within which the original judgment target (the true judgment area) is encompassed. Therefore, the captured timing of the image is determined based on the depth of field δ of the imaging device EQU, the depth of the inspection range, and the like.

The depth of field δ is an area in which the focus is approximately in focus with respect to the surface 6, as shown in FIG. 2(b). That is, the depth of field δ means the range that is substantially in focus. This depth of field depends on the focal length of the lens and the aperture. The image of an object existing in the depth of field exists within the image formation range (depth of focus) of the image sensor 7 such as CCD (Charge Coupled Device). In general, the depth of field generally becomes shallower as the focal length of the lens becomes shorter, and becomes deeper as the aperture is narrowed down.

In order to evaluate the quality of the end surface 10a of the semiconductor chip 10, the total magnification is preferably 10 to 20 times. Correspondingly, the depth of field δ is about δ=10 μm to 2 μm. Also, preferably, the image(s) is captured intermittently each time when the imaging device EQU moves a prescribed distance (imaging pitch) Pi, and the imaging pitch Pi is determined in consideration of the height dimension H of the inspection area(s), encompassing the judgment area (judgment target).

Referring now to FIG. 3 (a), it is assumed that the edge of the top surface of the semiconductor chip 10 is the origin line ORG (see FIG. 1(a)) and that the inspection range H is the range H downward from the origin line ORG. Also, FIG. 3 (b) and FIG. 3 (c) show the depth of field δ, and the imaging device EQU moves back and forth along the movement line LN of the tilt angle θ.

In such a case, on the outward path on the moving line LN, for example, the lowest line of the inspection range H can first be captured in the field of view in focus as shown in FIG. 3(b). That is, in the state of FIG. 3(b), the focal position F1 is located before X1 from the origin line ORG, and the position of +δ/2 from the focal position F1 coincides with the lower end (lowest line of H) of the inspection range.

In this case, H*SIN(θ)+X1=δ/2 . . . (Equation 1) holds, and by transposing this equation, X1=δ/2−H*SIN(θ). X1 does not necessarily have to be a positive value; it may be a negative value.

Next, as the imaging device EQU moves further forward on its outward path on the moving line, it reaches the state shown in FIG. 3(c), where the position −δ/2=−X2 from the focal position F2 coincides with the upper end of the inspection area H (i.e., the origin line ORG). In this state of FIG. 3(c), the relationship X2=δ/2 . . . (Equation 2) is established.

In the state shown in FIG. 3(c), as the imaging device EQU needs to capture the image(s) including the lowest end (+H line) of the inspection range, the relationship H*SIN(θ)≤δ . . . (Equation 3) is required. Since (Equation 3) defines the tilt angle θ, once the inspection range H and depth of field δ are determined, the tilt angle θ must satisfy the relationship SIN(θ)≤δ/H . . . (Equation 3). This relationship also holds in the case of FIG. 3(b).

Based on (Equation 1) and (Equation 2), the equation X1+X2=δ−H*SIN(θ) . . . (Equation 4) is calculated. If images are captured at Pi=X1+X2 or within a smaller distance range, images in focus in the inspection area H can always be captured. Therefore, the imaging pitch Pi on the moving line must be Pi≤δ−H*SIN(θ) . . . (Equation 4).

Even when the imaging pitch Pi is the highest pitch Pi=δ−H*SIN(θ), if imaging is repeated at a uniform pitch Pi from any imaging start timing, a single image can always be captured somewhere between the focal position F1 and the focal position F2. Therefore, in the present invention, the maximum value of the imaging pitch Pi is determined based on the inclination angle θ of the moving line, the vertical dimension H of the inspection area, and the depth of field δ.

By adopting this configuration, the captured image at the optimum timing will always include the intended inspection area within the depth of field δ, and so an image of the inspection area in focus can be acquired. In this embodiment, the intended inspection area is the region from the origin line ORG down to +H. For example, when the depth of field δ=14 μm, the inspection range H=10 μm, and the inclination angle θ=40°, the imaging pitch Pi is a condition of Pi≤7.5 μm. By narrowing the imaging pitch Pi from the highest value=7.5 μm, multiple in focus images can be obtained.

Next, to examine the condition of tilt angle θ, assume that the depth of field δ=10 μm at inspection range H=10 μm. In this case, if the imaging pitch Pi is the maximum value δ−H*SIN(θ), SIN(θ)≤10/10 holds based on (Equation 3), so the tilt angle θ can be any value. Thus, in this case, the inclination angle θ can be set to a limit value by employing the staggered arrangement shown in FIG. 1(c).

Also, in the case where the imaging pitch Pi is at its maximum value δ−H*SIN(θ), if H=5 μm and the depth of field δ=2 μm, SIN(θ)≤0.4 holds based on (Equation 3), which means θ≤23.50. However, where the imaging pitch Pi is shorter than the maximum value δ−H*SIN(θ), the tilt angle θ does not necessarily need to satisfy the relationship SIN(θ)≤δ/H (Equation 3).

In any event, the present invention captures a plurality of images at the predetermined imaging pitch Pi. In FIGS. 4(a)-4(e), five images obtained from the same semiconductor chip 10 at the imaging pitch Pi are shown, including images in which the inspection area is out of focus and images with a less defined focus. Although each image captures an end surface 10a of the semiconductor chip 10, a virtual image of the semiconductor chip 10 is also captured because the placement surface 40 has light reflectivity.

In the present invention, it is necessary to select the most focused image from a plurality of images as shown in FIG. 4. Therefore, an evaluation line EVL, which is continuous from the outside to the inside of the semiconductor chip 10, is defined in the present invention, and image data along the evaluation line EVL is extracted (first means).

While not specifically limited, the evaluation line EVL is typically a straight line extending from the outside to the inside of the end surface 10a of the semiconductor chip 10, intersecting the origin line ORG (FIG. 3(a)). These evaluation lines EVL are represented by the white lines in FIGS. 4(a) to 4(e). The intersecting evaluation line does not necessarily need to be orthogonal to the origin line ORG.

In the case where the image captured by the imaging device EQU is an RGB color image, the extracted data along the evaluation line EVL is preferably one-dimensional data. For instance, brightness data (V value) obtained through HSV conversion of RGB data is suitably used as the extraction data. In HSV conversion, the maximum value among R (Red), G (Green), and B (Blue) in RGB space is selected as the V value (Value of Brightness).

If any single color of RGB has a strong change in brightness, it is preferable to use light amount data that has been passed through an appropriate single-color filter. Furthermore, images are not limited to color images, and may be monochrome images.

Also, the quality of the focus is assessed based on the sharpness of the edge detected from the extraction data, and the image with the sharpest edge is selected as the optimal focus image. In the example of FIG. 4, the image 4 or image 5 is selected as the optimal image.

The above operations are implemented through computer processing. The brightness data (V value) obtained by HSV conversion is smoothed, for example, using averaging processing, and positive and negative edges are extracted by, for example, differentiating the smoothed data.

The positive or negative edge is binarized based on a predetermined threshold (TH) to generate a pulse wave. The pulse width is then evaluated, and the image with the narrowest pulse width is selected as the optimum image (second means). The choice between positive and negative edges depends on the direction of change (positive or negative level difference) in the brightness (V value) inside and outside of the semiconductor chip 10.

FIG. 5(a) illustrates the HSV brightness data, and FIG. 5(b) shows the waveform after averaging the brightness data. FIG. 5(c) shows the averaged waveform after differential processing, and FIG. 5(d) shows the pulse wave after the binarization process. As shown, the brightness data (FIG. 5(a)) exhibits delicate level variations, but averaging processing effectively removes micro-level components.

The averaging process is implemented, for example, through a convolution operation (see FIG. 5 (b)), where three consecutive pieces of data, including one before and one after, are averaged (see FIG. 5 (b)). The differentiation process is realized, for example, by a difference operation between the data one before and one after (see FIG. 5(c)). However, the above process is not limited in any way, and any appropriate digital filter process can be used to realize substantially integral and differential processing.

In any case, the pulse waves obtained by executing the averaging,→differentiation,→and binarization processes for the brightness data on the evaluation line EVL of all captured images are evaluated. Then the image with the smallest pulse width is selected as the optimal image. In the case of an out-of-focus image, the pulse width of the binarized signal becomes wider because the data after differentiation processing changes slowly, as shown in FIG. 5 (a). Hereafter, the process of obtaining the pulse wave by averaging,→differentiation,→and binarization processing may be referred to as ‘edge detection processing.’

When the optimum image is selected as described above, the optimum image identified by the second means is then assessed based on the previously captured standard image, and the quality of the semiconductor chip 10 corresponding to the optimum image is determined (third means).

Although the specific method of the third means is arbitrary, for example, a boundary portion showing a significant difference in brightness is identified based on the edge detection processing, and the background of the captured image is first removed. At this time, it is preferable that the virtual image reflected on the mounting table 40 is also removed based on the edge detection processing or the like.

Subsequently, the captured image is evaluated from the viewpoint of whether there are any scratches or dust on the semiconductor chip 10. Various methods can be employed for this purpose, such as calculating the similarity between the captured image and the standard image based on pre-extracted feature point(s) and feature value(s). Then, based on the evaluation value (similarity), the quality of the semiconductor chip 10 corresponding to this image is determined. In this case, the use of deep learning techniques is also a viable option. If the objective is merely to ascertain the presence or absence of a flaw or dust, an alternative approach is to assess the quality of the semiconductor chip 10 by examining the transition of brightness data along a suitable evaluation line. The transition of brightness data is determined based on, for example, the number of pulses and/or the pulse width for the pulse wave(s) after the edge detection process.

### Effect of the Invention

As described above, according to the present invention, it is possible to quickly and reliably determine the quality of the end surface of the semiconductor chip.

### BRIEF DESCRIPTION OF THE DRAWINGS

FIG. 1 is a drawing for explaining an arrangement state of a semiconductor chip and an operation of an imaging apparatus.

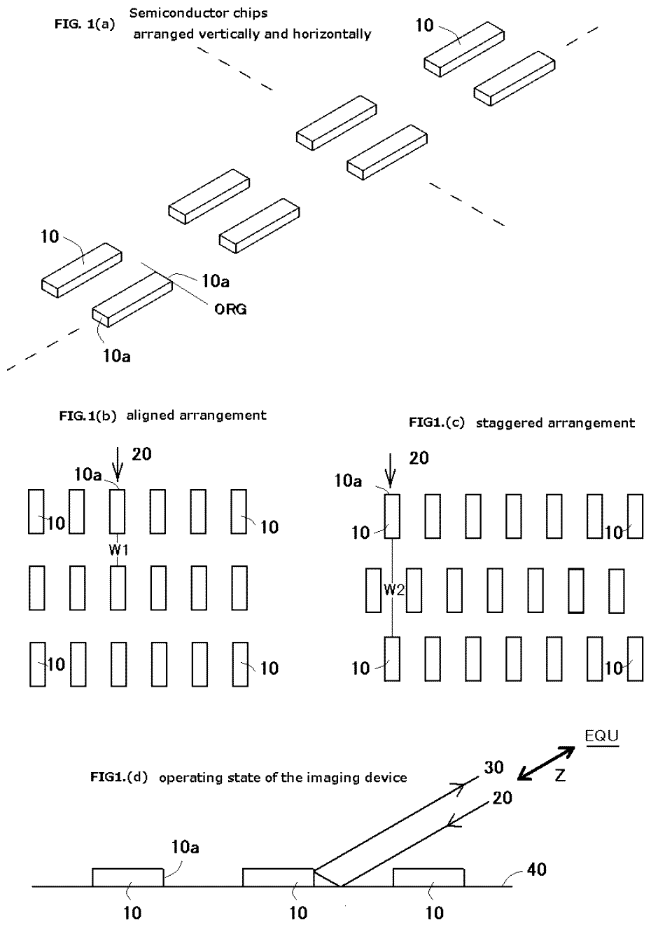

FIG. 2 is a drawing illustrating a configuration of an imaging apparatus and a depth of field.

FIG. 3 is a drawing for explaining a maximum value of a photographing pitch.

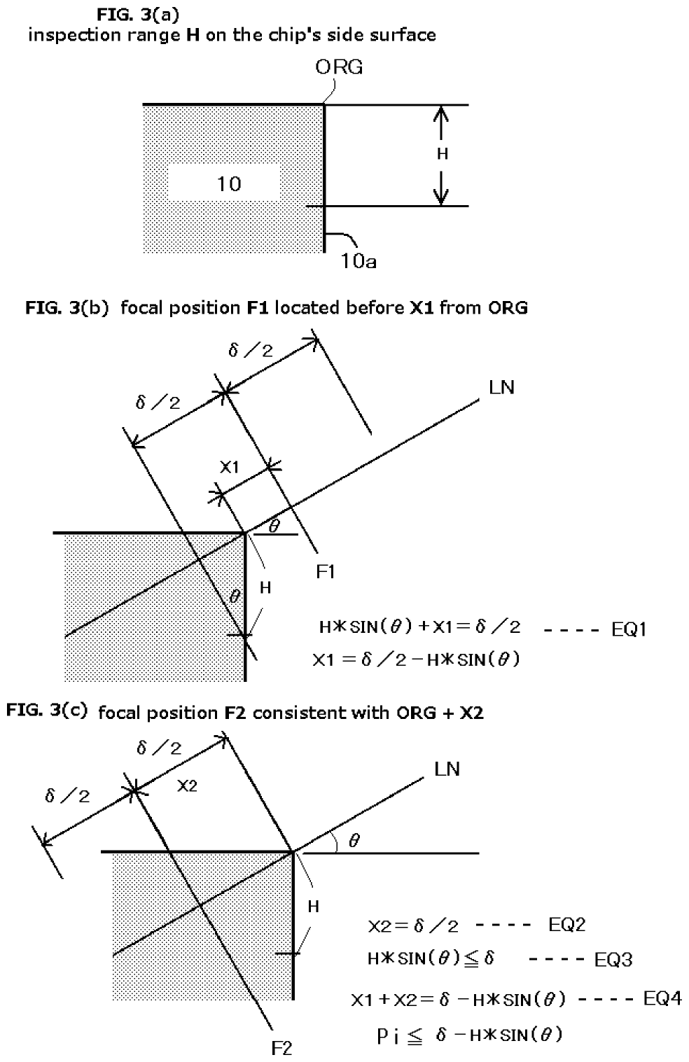

FIG. 4 illustrates sampling images.

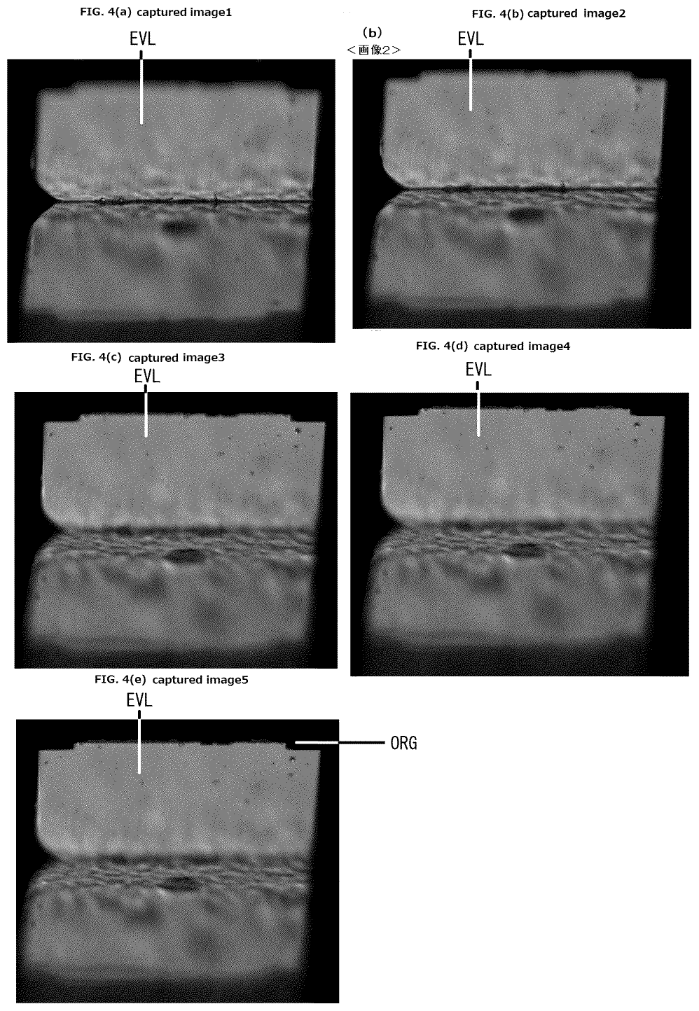

FIG. 5 illustrates a procedure for data processing.

FIG. 6 is a diagram illustrating the operation of an embodiment.

### DETAILED DESCRIPTION OF THE INVENTION

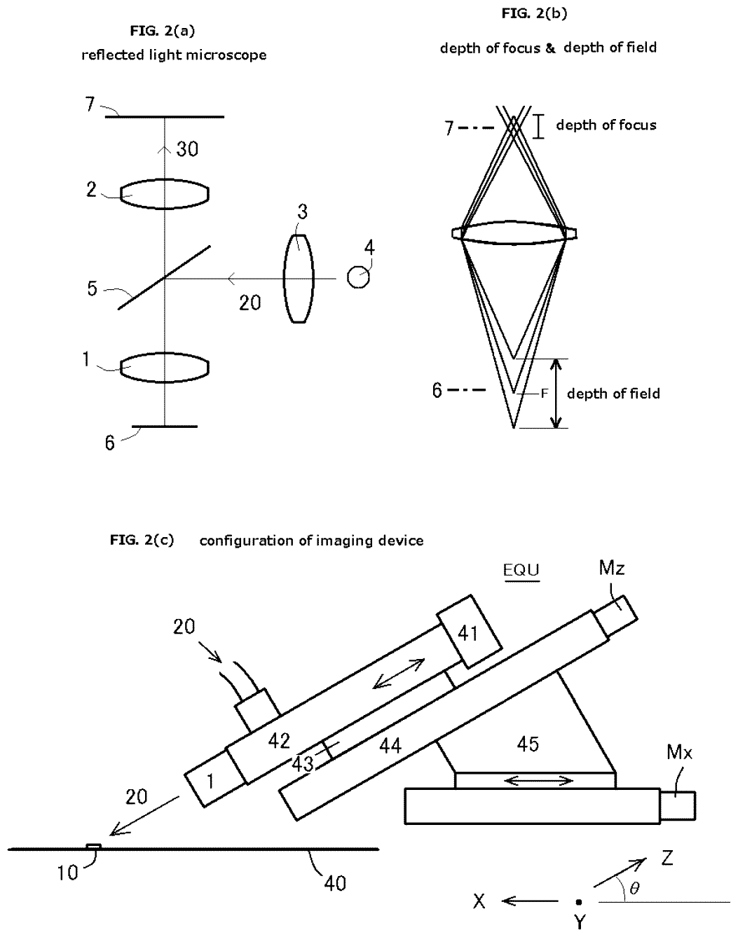

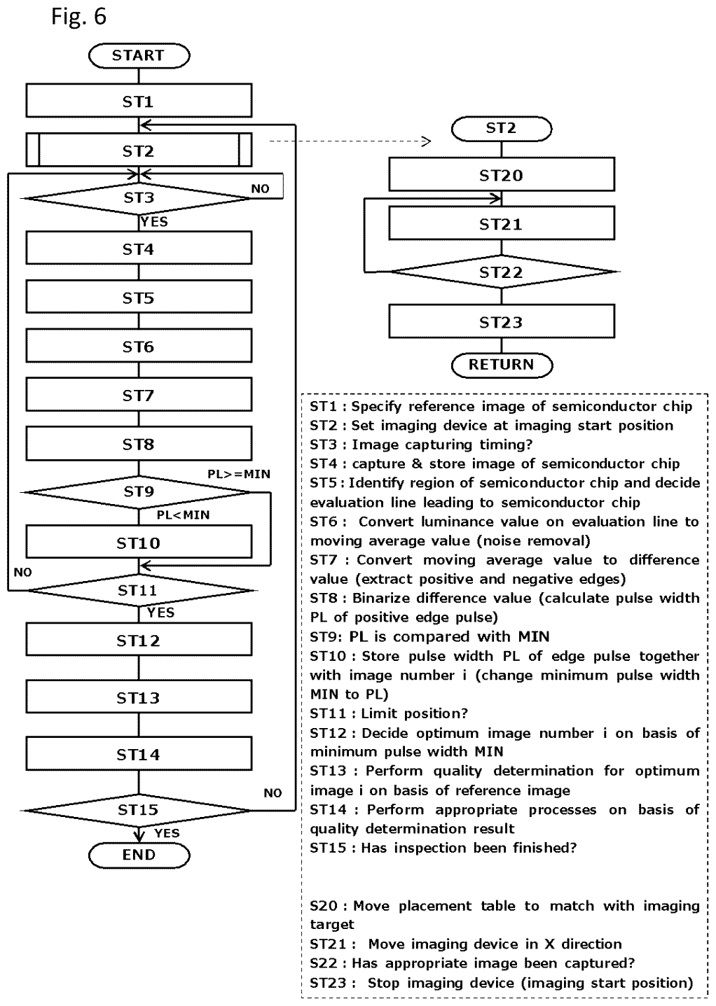

Hereinafter, the present invention will be described in detail based on examples, but these embodiments are merely illustrative examples, and the specific contents of the description do not limit the present invention in any way. FIG. 6 is a flowchart explaining the operation of the imaging device EQU and the determination device. The determination device controls the operation of the imaging system EQU with a built-in grazing microscope whose basic configuration is shown in FIG. 2(a).

The imaging device EQU of the embodiment has the basic configuration shown in FIG. 2(c), and consists of a stepping motor Mx for reciprocating motion in X direction and a stepping motor Mz for reciprocating motion in Z direction. In this embodiment, the movement line LN of the imaging device EQU is inclined at θ=30° with respect to the mounting surface 40 on which semiconductor chips 10 are placed.

Based on the above conditions, the imaging pitch Pi must be Pi≤δ−H*SIN(30)=δ−H/2 with respect to the depth of field δ and the height dimension H of the inspection area. Therefore, considering the depth of field δ=10 μm and the height dimension H=10 μm of the inspection range, the imaging pitch Pi of this embodiment is set to Pi=4 μm, which is slightly narrower than the maximum value of 5 μm. When the pulse speed of the stepping motor Mz is, for example, 1400 PPS (pulse per second), the side surface (end surface) 10a of the semiconductor chip 10 is repeatedly photographed every 40 pulses. In this operating condition, the imaging period is 40/1400=28.6 mS.

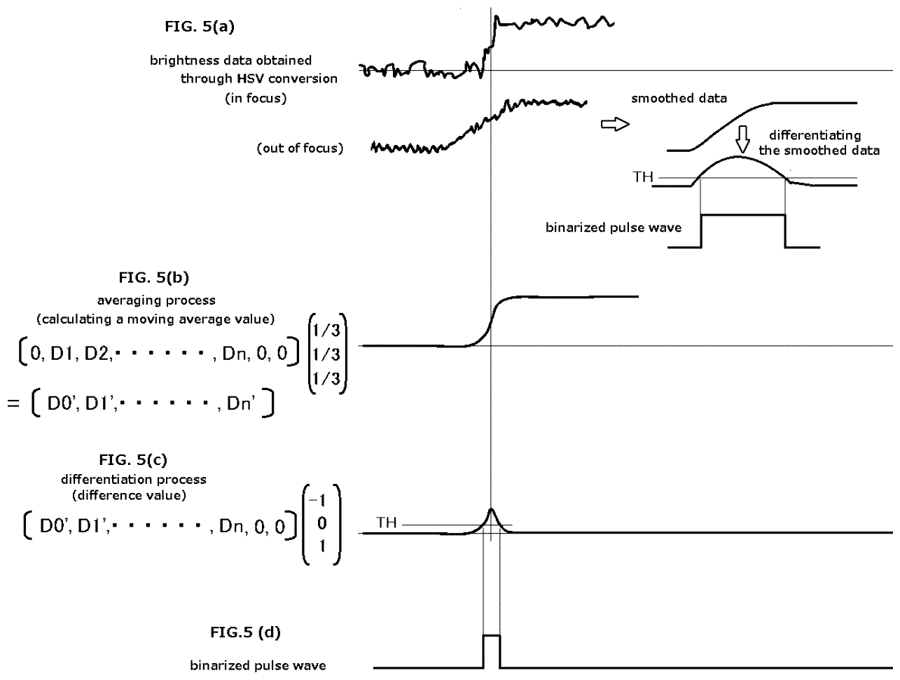

In light of the above, referring to the flowchart of FIG. 5, first, characteristic parameters are identified from the reference image (standard image) of the reference chip that is a typical non-defective semiconductor chip 10 (ST1). Also, the range H1/HMAX to H2/HMAX in the horizontal direction from the left end of the reference chip and the range V1/VMAX to V2/VMAX in the vertical direction from the upper end are specified for a reference region, which is the quality determination region of the reference chip.

It should be noted that the quality determination region does not necessarily have to be one region for one semiconductor chip 10, and may be a plurality of regions. If three quality determination regions AR1-AR3 are required, the first region AR1 closest to the objective lens 1, for example, is used as the reference region. And the optimal images of other quality determination regions AR2 and AR3 are identified based on their relative positions to the reference region AR1.

When capturing images while moving the imaging device EQU closer to the semiconductor chip, the second and third regions, AR2 and AR3, are defined based on their relative positional relationship to the reference region (first region AR1). And the images i+n and i+m, where n and m represent deviations from the optimal image i capturing the first region AR1, are identified as the optimal images for the second and third regions, AR2 and AR3, respectively.

On the other hand, when capturing images while moving the imaging device EQU away from the semiconductor chip, as in the present embodiment, the third region AR3, which is farthest from the objective lens 1, is selected as the reference region. Therefore, the images i+n and i+m, where n and m represent deviations from the optimal image i capturing the third region AR3, are identified as the optimal images for the second and first regions, AR2 and AR1, respectively.

Next, the imaging device EQU is set to a start position for photographing. The setting procedure of the start position for photographing is as shown in FIG. 2 (c). First the mounting table 40 is moved to an optimal position in the horizontal plane XY according to the arrangement position of the semiconductor chips 10 as captured image targets (ST20). If necessary, the mounting table 40 may be moved in the vertical and/or inclined direction. In this case, the inclination angle θ between the mounting platform 40 and the line of movement LN of the imaging device EQU can be appropriately changed. In any event, as a result of these movement operations, the semiconductor chip 10, which is the target for photography, is brought into close proximity to the imaging device EQU, and the imaging device EQU is set to its initial position.

Next, the imaging device EQU is moved forward or backward in the X direction to bring the chip's end surface 10a to the center of the imaging screen appearing large up to the limit state. Since the movement in the X direction is performed with an accuracy of, for example, 1 μm, an accurate positioning operation is possible. Also, the imaging device EQU moves to the optimal position (ST21) based on the microscope image, in addition to the movement of the mounting table 40 (ST20) based on the planar image of the semiconductor chips 10 captured by the camera. Therefore, in the present embodiment, the precise positioning is achieved. However, at this timing, a focused captured image has not yet been obtained.

Next, to obtain a focused captured image, the imaging device EQU initiates backward movement (ST2). While forward movement could be performed instead, in this embodiment, backward movement is employed in accordance with the positioning operation of step ST2.

After the photographing operation begins, it is determined whether the capturing timing (+40 pulses have elapsed, for example) has been reached (ST3), and when the image capturing timing has been reached, the end surface 10a of the semiconductor chip 10 is photographed and the image is stored (ST4). Next, the outline of the semiconductor chip 10 is determined in the obtained image, and an evaluation line extending from the top of the semiconductor chip 10 to the main body of the semiconductor chip 10 is specified (ST5).

Subsequently, averaging processing such as calculating a moving average value is performed on the brightness data on the evaluation line to remove the noise (ST6), and the data after the noise processing is differentiated to detect the positive and negative edges (ST7).

Next, in this embodiment, focusing on the positive edge, the positive edge is binarized based on a predetermined threshold TH (ST7), and the pulse width PL of the pulse wave after binarization is calculated (ST8). Then, the pulse width PL is compared with the previous minimum value MIN, and if PL<MIN, the minimum value MIN is rewritten to the current pulse width PL and the image number i corresponding to the pulse width PL is stored (ST10).

The above described processes from ST4 to ST10 are repeated for each capturing. Then, when the imaging device moves away from the semiconductor chip 10 to a limit position, the imaging device EQU is returned to the photographing start position, and an optimal image is identified based on the image number i corresponding to the minimum value MIN that is stored at that time (ST12).

If the above processing ends, the background image is removed for the specified optimal image i, and the necessary feature parameters are calculated. Next, the similarity is calculated based on the comparison the calculated parameters with the feature parameters of the reference image, and then the quality of the semiconductor chip 10 corresponding to the optimum image i is determined (ST13).

Then, for the semiconductor chip 10 evaluated as a defective, the placement position or the like on the placement surface is stored and left to the necessary processing (ST14). Since the quality determination of the specific one semiconductor chip 10 is completed by the above processing, the processing of ST3 to ST25 will be repeated for the adjacent semiconductor chips 10.

While the embodiment has been described in detail above, the specific configuration can be appropriately varied without departing from the spirit of the invention. For instance, in this embodiment, although the chip's end surface is captured while stationary, it might also be photographed during movement due to the slow speed of motion. Moreover, the method for detecting the minimum pulse width PL is not confined to the sequential operation depicted in FIG. 6. For instance, after capturing and storing all the necessary images, edge extraction processing can be carried out for each image, and batch processing to select the optimal image is also a viable approach.

### CODE DESCRIPTION

ST5: First means
ST12: Second means
ST13: Third means

1. An apparatus for determining a semiconductor chip, the apparatus comprising:
an imaging device that reciprocates obliquely above the semiconductor chip disposed on a light-reflective mounting surface to capture an image of the semiconductor chip's end surface, and a determination device that determines the quality of the semiconductor chip based on the image captured by the imaging device,
wherein the determination device comprises:
a first means for extracting data on an evaluation line continuous inside and outside of the semiconductor chip from each of a plurality of images captured during the movement of the imaging device;
a second means for identifying an optimum image from the plurality of images by evaluating the change mode of data on the evaluation lines for each of said images; and
a third means for determining the quality of the semiconductor chip by assessing the optimal image identified by the second means based on a previously captured standard image.

2. The apparatus according to claim 1, wherein the imaging device reciprocates at a tilt angle of 20° to 40° with respect to the mounting surface.

3. The apparatus according to claim 1, wherein the imaging device captures a magnified image of a predetermined magnification.

4. The apparatus according to claim 4, wherein the plurality of images are intermittently captured in a stop state or a moving state every time the imaging device moves by a specified distance, and
the specified distance is determined based on the tilt angle δ during movement of the imaging device, a vertical dimension H of an inspection range required for quality determination, and a depth of field δ.

5. The apparatus according to claim 1, wherein the data on the evaluation line is brightness data.

6. The apparatus according to claim 1, wherein the second means selects an image showing the most sharp transition mode as an optimal image.

7. The apparatus according to claim 6, wherein the second means evaluates the transition mode based on the differential processing value of the data on the evaluation line.

8. The apparatus according to claim 1, wherein the imaging device is reciprocally movable on a horizontal plane.

9. The apparatus according to claim 1, wherein the semiconductor chip is arranged in a staggered manner in a plan view, so that a gap in the direction of the illumination light is widely secured.

10. The apparatus according to claim 1, wherein a plurality of quality determination regions including a standard determination region are specified in the semiconductor chip, and
an optimal image is selected from the plurality of captured images corresponding to the optimal image of the standard determination region.

11. A method for determining a semiconductor chip using an imaging device and a determination device: the imaging device that reciprocates obliquely above the semiconductor chip disposed on a light-reflective mounting surface to capture an image of the semiconductor chip's end surface, the determination device that determines the quality of the semiconductor chip based on the image captured by the imaging device,
wherein the method comprises:
a first step of extracting data on an evaluation line continuous inside and outside of the semiconductor chip from each of a plurality of images captured during the movement of the imaging device;
a second step of identifying an optimum image from the plurality of images by evaluating the change mode of data on the evaluation lines for each of said images; and
a third step of determining the quality of the semiconductor chip by assessing the optimal image identified by the second step based on a previously captured standard image.
